(19) United States
(12) Patent Application Publication
(10) Pub. No.: US 2026/0190833 A1
(43) Pub. Date: Jul. 2, 2026

(54) DISPLAY DEVICE

(71) Applicant: LG Display Co., Ltd., Seoul (KR)

(72) Inventors: Jeongbeom LEE, Seoul (KR); Jungeun LEE, Seoul (KR); HwanKeon LEE, Gimpo-si (KR); Junhyeok LEE, Seoul (KR)

(73) Assignee: LG Display Co., Ltd., Seoul (KR)

(21) Appl. No.: 19/402,384

(22) Filed: Nov. 26, 2025

(30) Foreign Application Priority Data
Dec. 27, 2024 (KR) 10-2024-0198209

(51) Int. Cl. H10K 59/80; H10K 59/12; H10K 59/40; H10K 102/00

(52) U.S. Cl. CPC H10K 59/8792; H10K 59/1201; H10K 59/40; H10K 59/873; H10K 59/879; H10K 2102/351

(57) ABSTRACT

According to an aspect of the present disclosure, a display device includes a substrate having an active area in which a plurality of sub-pixels is disposed and a non-active area adjacent to the active area. A plurality of light emitting elements is disposed in the plurality of sub-pixels on the substrate, and an encapsulation structure disposed to cover the plurality of light emitting elements. A touch sensing unit including a plurality of touch electrodes is disposed on the encapsulation structure. A black matrix is disposed on the touch sensing unit, and a plurality of metal patterns is disposed within openings of the black matrix on the same layer. An organic dye layer is disposed on the plurality of metal patterns to improve optical characteristics. Accordingly, the display device can reduce reflection caused by external light and enhance display visibility while maintaining a simplified and compact structure.

### CROSS-REFERENCE TO RELATED APPLICATIONS

This application claims the priority of Korean Patent Application No. 10-2024-0198209 filed on December 27, 2024, in the Korean Intellectual Property Office, the disclosure of which is incorporated herein by reference.

### TECHNICAL FIELD

The present disclosure relates to a display device, and more particularly, to a display device capable of reducing reflection due to external light.

### DESCRIPTION OF THE RELATED ART

As it enters the information age, the field of display devices that visually display electrical information signals is rapidly developing, and research is being conducted to develop performances such as thinning, weight reduction, and low power consumption for various display devices.

Representative display devices include a liquid crystal display (LCD), a field emission display (FED), an electro-wetting display (EWD), and an organic light emitting display (OLED).

An electroluminescent display device represented by an organic light emitting display device is a self-emitting display device and does not require a separate light source unlike a liquid crystal display device. Therefore, the electroluminescent display device can be manufactured to have a light weight and a small thickness. In addition, the electroluminescent display device is advantageous in terms of power consumption because the electroluminescent display device operates at a low voltage. Further, the electroluminescent display device is expected to be utilized in various fields because the electroluminescent display device is excellent in implementation of colors, response speeds, viewing angles, and contrast ratios (CRs).

### BRIEF SUMMARY

The present disclosure relates to a display device structure that reduces reflection from external light while simplifying fabrication. This is achieved through a co-layered arrangement of a black matrix and metal patterns, with the metal patterns positioned within openings of the black matrix and on the same layer. This configuration prevents corrosion of the metal patterns caused by the developer used for the black matrix and ensures that external light is absorbed rather than reflected, improving contrast and visibility.

An organic dye layer is arranged above the metal patterns to further suppress reflection and enhance optical performance. The dye layer may be formed as a continuous film covering both emission and non emission areas, or as discrete regions corresponding to each sub pixel. By forming the dye layer through inkjet or photo application, multiple masking steps are avoided, resulting in reduced process time, lower production cost, and a thinner display structure compared with conventional devices that use separate color filters or polarizers.

The structure also employs a dual purpose metal pattern geometry in which a side portion of each metal pattern redirects light entering from lateral directions, thereby improving luminous efficiency. The use of materials for the black matrix that can be processed at low temperature minimizes thermal stress on the organic layers. These features provide a display panel that offers reduced reflection, improved durability, simplified manufacturing, and enhanced optical performance.

Various embodiments of the present disclosure provide a display device capable of reducing reflectance due to external light.

Various embodiments of the present disclosure provide a display device capable of reducing a process cost and a process time of the display device.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate including an active area in which a plurality of sub-pixels is disposed and a non-active area surrounding the active area, a plurality of light emitting elements disposed in the plurality of sub-pixels on the substrate, an encapsulation structure disposed to cover the plurality of light emitting elements, a touch sensing unit disposed on the encapsulation structure and including a plurality of touch electrodes, a black matrix disposed on the touch sensing unit, a plurality of metal patterns disposed in an opening of the black matrix, and an organic dye layer disposed on the plurality of metal patterns.

A display device according to another exemplary embodiment of the present disclosure includes a substrate, a plurality of light emitting elements disposed on the substrate, an encapsulation structure disposed to cover the plurality of light emitting elements, a touch sensing unit disposed on the encapsulation structure and including a plurality of touch electrodes, a black matrix disposed on the touch sensing unit and including an opening overlapping an emission area of the plurality of light emitting elements, a plurality of metal patterns positioned on the same layer as the black matrix and disposed in the opening of the black matrix to overlap the emission area of the plurality of light emitting elements, and an organic dye layer disposed to cover the plurality of metal patterns.

Other detailed matters of the embodiments are included in the detailed description and the drawings.

In the display device of the present disclosure, a plurality of metal patterns is disposed to correspond to the emission areas of the plurality of light emitting elements, and an organic dye layer is disposed to overlap the emission areas and the non-emission areas of the plurality of light emitting elements, thereby improving reflectance in the emission areas of the plurality of light emitting elements.

In the display device of the present disclosure, the black matrix and the plurality of metal patterns are disposed on the same layer to prevent corrosion of the plurality of metal patterns due to the black matrix.

In the display device of the present disclosure, a portion of the plurality of metal patterns is disposed on a side surface of the black matrix to change a path of light directed toward the side surface of the plurality of black matrices, thereby improving luminous efficiency.

In the display device of the present disclosure, the mask process may be minimized or omitted by forming the organic dye layer by an application process such as inkjet or photo, and thus process optimization such as reducing process cost and process time may be possible.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram illustrating a display device according to an exemplary embodiment of the present disclosure.

FIG. 2 is a view schematically illustrating a circuit configuration of a sub-pixel according to an exemplary embodiment of the present disclosure.

FIG. 3 is a cross-sectional view taken along the line III-III′ of FIG. 1.

FIGS. 4A to 4C are schematic views illustrating a method of manufacturing a display device according to an exemplary embodiment of the present disclosure.

FIG. 5 is a schematic cross-sectional view of a display device according to another embodiment of the present disclosure.

FIG. 6 is a schematic cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

The features of various embodiments of the present disclosure can be partially or entirely adhered to or combined with each other and can be interlocked and operated in technically various ways, and the embodiments can be carried out independently of or in association with each other.

Hereinafter, an exemplary embodiments of the present disclosure will be described in detail with reference to accompanying drawings.

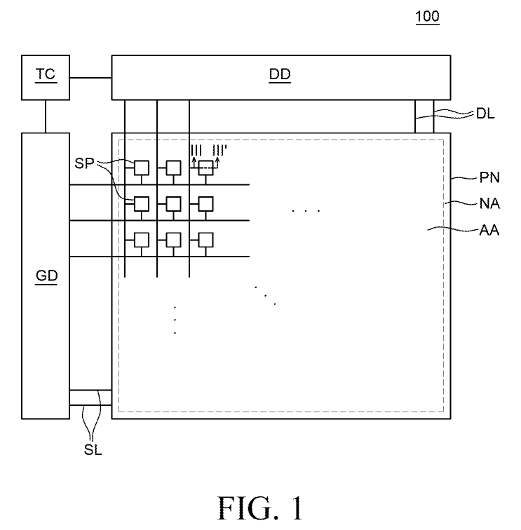

FIG. 1 is a block diagram illustrating a display device according to an exemplary embodiment of the present disclosure. FIG. 1 is a schematic block diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD supplies a data voltage to a plurality of data lines DL according to a plurality of data control signals and image data provided from the timing controller TC. The data driver DD may convert image data into a data voltage using a reference gamma voltage and supply the converted data voltage to a plurality of data lines DL.

The timing controller TC aligns image data input from the outside and supplies the image data to the data driver DD. The timing controller TC may generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub-pixels SP. In the display panel PN, the plurality of scan lines SL and the plurality of data lines DL may cross each other, and the plurality of sub pixels SP may be formed at intersections of the scan line SL and the data line DL. In the display panel PN, an active area AA and a non-active area NA may be defined.

The active area AA is an area in which images are displayed in the display device 100. In the active area AA, a plurality of sub pixels SP constituting a plurality of pixels and a pixel circuit for driving the plurality of sub pixels SP may be disposed. The plurality of sub-pixels SP is a minimum unit constituting the active area AA, and n sub-pixels SP may form one pixel. In each of the plurality of sub pixels SP, a thin film transistor for driving the plurality of light emitting elements is disposed so that the plurality of sub pixels SP may independently emit light. For example, the plurality of sub-pixels may include a first sub-pixel, a second sub-pixel, and a third sub-pixel that emit light of different colors. For example, the first sub-pixel may be a red sub-pixel that emits red light, the second sub-pixel may be a green sub-pixel that emits green light, and the third sub-pixel may be a blue sub-pixel that emits blue light, but is not limited thereto.

The plurality of light emitting elements may be differently defined depending on the type of the display panel PN. For example, when the display panel PN is an organic light emitting display panel, the light emitting element may be an organic light emitting element.

In the active area AA, a plurality of signal lines for transmitting various signals to the plurality of sub-pixels SP is disposed. For example, the plurality of signal lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL may extend in one direction in the active area AA and be connected to the plurality of sub pixels SP, and the plurality of data lines DL may extend in a direction different from the one direction in the active area AA and be connected to the plurality of sub pixels SP. In addition, in the active area AA, a low potential power line, a high potential power line, and the like may be further disposed, but are not limited thereto.

The non-active area NA is an area where an image is not displayed and may be defined as an area extending from the active area AA. In the non-active area NA, a link line and a pad electrode for transmitting a signal to the sub pixel SP of the active area AA, or a driving IC, such as a gate driver IC or a data driver IC, may be disposed.

Meanwhile, a driver such as a gate driver GD, a data driver DD, and a timing controller TC may be connected to the display panel PN in various ways. For example, the gate driver GD may be mounted in the non-active area NA in a gate-in-panel (GIP) manner or mounted between the plurality of sub pixels SP in the active area AA in a gate-in-active area (GIA) manner.

For example, the data driver DD and the timing controller TC are formed on separate flexible film and printed circuit board, and the display panel PN, the data driver DD, and the timing controller TC may be electrically connected by bonding the flexible film and the printed circuit board to the pad electrode formed in the non-active area NA of the display panel PN.

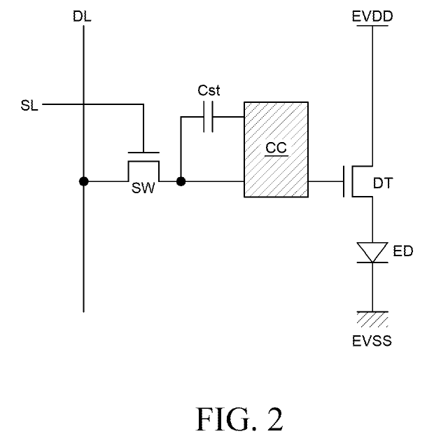

FIG. 2 is a view schematically illustrating a circuit configuration of a sub-pixel according to an embodiment of the present disclosure.

Referring to FIG. 2, one sub-pixel may include a switching transistor SW, a driving transistor DT, a capacitor Cst, a compensation circuit CC, and an organic light emitting element ED.

For example, the switching transistor SW may perform a switching operation so that a data signal supplied through the data line DL is stored in the capacitor Cst as a data voltage in response to a scan signal supplied through the scan line SL. Further, for example, the driving transistor DT may operate such that a driving current flows between the high potential power line EVDD and the low potential power line EVSS according to a data voltage stored in the capacitor Cst. Further, the organic light emitting element ED may operate to emit light according to a driving current formed by the driving transistor DT.

The compensation circuit CC is a circuit added to the sub-pixel to compensate for a threshold voltage of the driving transistor DT. The compensation circuit CC may include one or more transistors. The configuration of the compensation circuit CC may vary depending on an external compensation method.

The sub pixel illustrated in FIG. 2 is configured by a 2T (transistor) 1C (capacitor) structure including a switching transistor ST, a driving transistor DT, a capacitor Cst, and a light emitting element ED. When the compensation circuit 135 is added, the sub pixel may be configured in various forms, such as 3T1C, 4T2C, 5T2C, 6T1C, 6T2C, 7T1C, and 7T2C.

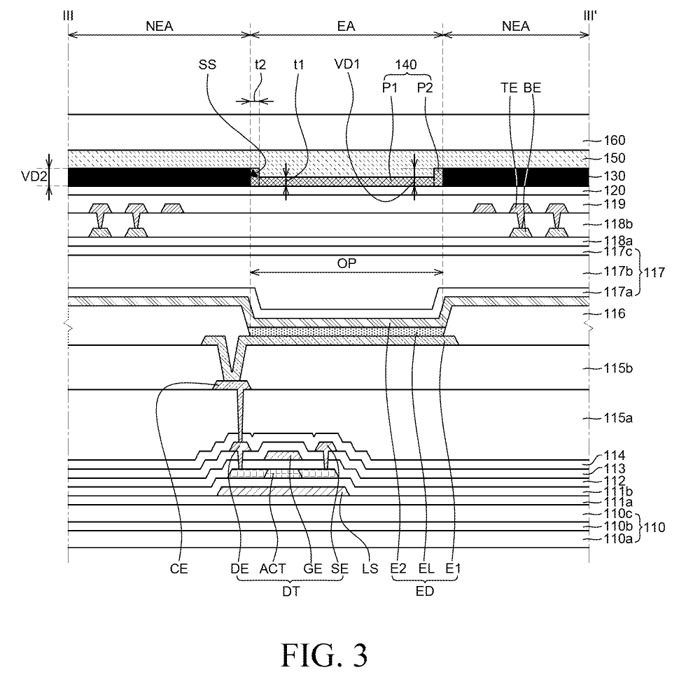

FIG. 3 is a cross-sectional view taken along the line III-III′ of FIG. 1. In FIG. 3, for the convenience of description, only components included in one sub pixel SP disposed in the active area AA are shown.

Referring to FIG. 3, the substrate 110 is a component for supporting various components included in the display device 100 and may be formed of an insulating material. The substrate 110 may include a first substrate 110a, an insulating layer 110b, and a second substrate 110c. The insulating layer 110b may be disposed between the first substrate 110a and the second substrate 110c. As described above, the substrate 110 is configured by the first substrate 110a, the second substrate 110c, and the insulating layer 110b to suppress moisture permeation. For example, the first substrate 110a and the second substrate 110c may be polyimide (PI) substrates.

The first buffer layer 111a is disposed on the substrate 110. The first buffer layer 111a may reduce permeation of moisture, oxygen, or impurities through the substrate 110. For example, the first buffer layer 111a may be configured as a single layer or multilayer made of silicon oxide (SiOx) or silicon nitride (SiNx). However, the present disclosure is not limited thereto.

The light shielding layer LS is disposed on the first buffer layer 111a in each of the plurality of sub-pixels. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize a leakage current.

The second buffer layer 111b is disposed on the substrate 110 and the light shielding layer LS. The second buffer layer 111b may reduce penetration of moisture or impurities through the substrate 110. For example, the second buffer layer 111b may be configured by a single layer or a double layer of silicon oxide (SiOx) or silicon nitride (SiNx), but is not limited thereto. However, the second buffer layer 111b may be omitted depending on the type of substrate 110 or the type of transistor, but is not limited thereto.

The driving transistor DT of each of the plurality of sub pixels SP is disposed on the second buffer layer 111b. The driving transistor DT is a transistor for controlling a driving current supplied to the light emitting element ED.

The driving transistor DT includes an active layer ACT, a gate electrode GE, a source electrode SE, and a drain electrode DE.

The active layer ACT of the driving transistor DT may be disposed on the second buffer layer 111b. For example, the active layer ACT may be formed of polysilicon (p-Si), amorphous silicon (a-Si), or an oxide semiconductor, but is not limited thereto.

The gate insulating layer 112 may be disposed on the active layer ACT. The gate insulating layer 112 is an insulating layer which insulates the active layer ACT from the gate electrode GE and may be formed of silicon oxide (SiOx), silicon nitride (SiNx), or a double layer thereof.

Further, the gate electrode GE of the driving transistor DT may be disposed on the gate insulating layer 112. The gate electrode GE is disposed on the gate insulating layer 112 so as to overlap the active layer ACT. The gate electrode GE may be formed of various conductive materials, such as magnesium (Mg), aluminum (Al), nickel (Ni), chromium (Cr), molybdenum (Mo), tungsten (W), gold (Au), or an alloy thereof, but is not limited thereto.

The interlayer insulating layer 113 may be disposed to cover the gate electrode GE. The interlayer insulating layer 113 is an insulating layer which protects components below the interlayer insulating layer 113 and may be configured by a single layer or a double layer of silicon oxide (SiOx) or silicon nitride (SiNx), but is not limited thereto.

The source electrode SE and the drain electrode DE of the driving transistor DT may be disposed on the interlayer insulating layer 113.

The source electrode SE and the drain electrode DE may be connected to one side and the other side of the active layer ACT, respectively, through contact holes provided in the interlayer insulating layer 113 and the gate insulating layer 112. The source electrode SE and the drain electrode DE may be formed of various conductive materials, such as magnesium (Mg), aluminum (Al), nickel (Ni), chromium (Cr), molybdenum (Mo), tungsten (W), gold (Au), or an alloy thereof, but are not limited thereto.

A portion of the active layer ACT overlapping the gate electrode GE is a channel region. One of the source electrode SE and the drain electrode DE is connected to one side of the channel region in the active layer ACT, and the other is connected to the other side of the channel region in the active layer ACT.

The passivation layer 114 may be disposed on the source electrode SE and the drain electrode DE. The passivation layer 114 is provided to protect the driving transistor DT and may be formed of an inorganic layer, for example, silicon oxide (SiOx), silicon nitride (SiNx), or a double layer thereof.

The first planarization layer 115a may be disposed on the passivation layer 114. The first planarization layer 115a may protect the driving transistor DT and planarize an upper portion thereof. The first planarization layer 115a may be configured by a single layer or a double layer, and for example, may be formed of photoresist or an acrylic-based organic material, but is not limited thereto.

The connection electrode CE may be disposed on the first planarization layer 115a.

The connection electrode CE may be connected to one of the source electrode SE and the drain electrode DE through a contact hole provided in the first planarization layer 115a.

The second planarization layer 115b may be disposed on the connection electrode CE. The second planarization layer 115b may be made of the same material as the first planarization layer 115a.

The light emitting element ED including the first electrode E1, the organic layer EL, and the second electrode E2 may be positioned on the second planarization layer 115b.

Hereinafter, a stack structure of the light emitting element ED will be described in detail.

The first electrode E1 may be disposed on the second planarization layer 115b. In this case, the first electrode E1 may be electrically connected to the connection electrode CE through a contact hole provided in the second planarization layer 115b. The first electrode E1 may be formed of a metallic material.

For example, when the display device 100 is a top emission type in which light emitted from the light emitting element ED is emitted above the substrate SUB on which the light emitting element ED is disposed, the first electrode E1 may include a transparent conductive layer and a reflective layer. The transparent conductive layer may be made of a transparent conductive oxide such as ITO or IZO, and the reflective layer may be made of, for example, silver (Ag), aluminum (Al), gold (Au), molybdenum (Mo), tungsten (W), chromium (Cr), or an alloy thereof.

The bank 116 may be disposed while covering the end of the first electrode E1 to define an emission area. A portion of the bank 116 corresponding to the emission area of the sub-pixel SP may be opened. A part of the first electrode E1 may be exposed through the open part of the bank 116 (hereinafter, referred to as an open area). In this case, the bank 116 may be made of an inorganic insulating material, such as silicon nitride (SiNx) or silicon oxide (SiOx), or an organic insulating material, such as benzocyclobutene-based resin, acrylic-based resin, or imide-based resin, but is not limited thereto.

The bank 116 may be configured as a black bank 116 including a light absorbing material. For example, the light absorbing material may include carbon or black ink. The black bank 116 may prevent light emitted from the light emitting element ED from being directed to a side surface, thereby preventing color mixture between adjacent sub pixels SP and preventing reflection of external light. Furthermore, even if the polarization layer is not disposed, it is possible to prevent light leakage defects or the like.

The organic layer EL may be disposed on the bank 116. Accordingly, the organic layer EL may be disposed on the first electrode E1 exposed through the open area of the bank 116.

The organic layer EL is a layer for emitting light of a specific color and may have a structure separated for each sub pixel SP. The organic layer EL may include a plurality of organic material layers. For example, the organic layer EL disposed in the sub-pixel SP emitting red light may include an organic layer emitting red light, the organic layer EL disposed in the sub-pixel SP emitting green light may include an organic layer emitting green light, and the organic layer EL disposed in the sub-pixel SP emitting blue light may include an organic layer emitting blue light. The sub-pixel SP emitting red light, the sub-pixel SP emitting green light, and the organic layer EL disposed in the sub-pixel SP emitting blue light may be separately disposed.

The second electrode E2 may be disposed on the organic layer EL and the bank 116.

The light emitting element ED may be formed by the first electrode E1, the organic layer EL, and the second electrode E2.

The encapsulation structure 117 may be located on the light emitting element ED described above. In the present disclosure, the term “encapsulation structure” refers to one or more encapsulation layers that collectively cover and protect the light-emitting elements. The encapsulation structure may include a single encapsulation layer or a plurality of alternating inorganic and organic layers. Accordingly, the terms “encapsulation structure” and “encapsulation layer” may be used interchangeably depending on whether a single or multilayer configuration is employed.

The encapsulation structure 117 may have a single-layered structure or a multi-layered structure. For example, the encapsulation structure 117 may include a first encapsulation layer 117a, a second encapsulation layer 117b, and a third encapsulation layer 117c.

In this case, the first encapsulation layer 117a and the third encapsulation layer 117c may be configured by inorganic layers, and the second encapsulation layer 117b may be configured by an organic layer. Among the first encapsulation layer 117a, the second encapsulation layer 117b, and the third encapsulation layer 117c, the second encapsulation layer 117b is thickest and may serve as a planarization layer.

The first encapsulation layer 117a is disposed on the second electrode E2 and may be disposed to be most adjacent to the light emitting element ED. The first encapsulation layer 117a may be formed of an inorganic insulating material on which low-temperature deposition may be performed. For example, the first encapsulation layer 117a may be made of silicon nitride (SiNx), silicon oxide (SiOx), silicon oxynitride (SiON), or aluminum oxide (Al2O3). Since the first encapsulation layer 117a is deposited in a low temperature atmosphere, it is possible to prevent damage to the organic layer EL including an organic material vulnerable to a high temperature atmosphere during the deposition process.

The second encapsulation layer 117b may be formed to have a smaller area than that of the first encapsulation layer 117a. In this case, the second encapsulation layer 117b may be formed to expose both ends of the first encapsulation layer 117a. The second encapsulation layer 117b may serve as a buffer to alleviate stress between layers and to enhance planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may be formed by an inkjet method, but is not limited thereto.

The third encapsulation layer 117c may be formed above the substrate 110 on which the second encapsulation layer 117b is formed so as to cover upper surfaces and side surfaces of the second encapsulation layer 117b and the first encapsulation layer 117a. In this case, the third encapsulation layer 117c may minimize or block the permeation of external moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al2O3).

A touch sensing structure (also referred to as ‘a touch sensing unit’) may be disposed on the encapsulation structure 117 described above.

Specifically, the touch sensing unit may include a touch buffer layer 118a disposed on the encapsulation structure 117, a bridge electrode BE disposed on the touch buffer layer 118a, a touch interlayer insulating layer 118b disposed on the touch buffer layer 118a and the bridge electrode BE, and a plurality of touch electrodes TE disposed on the touch interlayer insulating layer 118b.

The touch buffer layer 118a may block a chemical solution such as a developer or an etching solution used in the manufacturing process of touch electrodes formed on the touch buffer layer 118a or external moisture or foreign substances from penetrating into the light emitting element.

The plurality of touch electrodes TE may include a plurality of first touch electrodes extending in a first direction and a plurality of second touch electrodes extending in a second direction intersecting the first direction.

For example, the plurality of first touch electrodes and the plurality of second touch electrodes may be disposed on the same layer. However, in an area where the plurality of first touch electrodes and the plurality of second touch electrodes intersect, the plurality of second touch electrodes may be separately disposed, and the plurality of separated second touch electrodes may be connected by the bridge electrode BE. A touch interlayer insulating layer 118b may be disposed between the plurality of second touch electrodes and the bridge electrode BE.

The first protective layer 119 may be disposed to cover the touch sensing unit. The first protective layer 119 may be formed of an organic insulating layer. The first protective layer 119 may protect the touch sensing unit and planarize an upper portion thereof. Further, the step at the upper layer of the display device 100 is prevented by the first protective layer 119 to improve the visibility of the display device 100.

The third buffer layer 120 may be disposed on the first protective layer 119. The third buffer layer 120 may reduce the penetration of moisture, oxygen, or impurities through the upper portion of the display device 100. For example, the third buffer layer 120 may be configured by a single layer or a double layer of silicon oxide (SiOx) or silicon nitride (SiNx), but is not limited thereto.

The black matrix 130 may be disposed on the third buffer layer 120. For example, the black matrix 130 may be provided in an integrated mesh shape to correspond to the non-emission area NEA of the plurality of light emitting elements ED, but is not limited thereto.

The black matrix 130 may include a light absorbing material that absorbs a visible light wavelength band. That is, the black matrix 130 may be a kind of a light blocking member. For example, the black matrix 130 may be made of a material that may be processed at a low temperature of about 100°C or less, preferably about 85°C or less. When the black matrix 130 is made of a material capable of performing a low-temperature process, thermal damage to the light emitting element ED due to the formation of the black matrix 130 may be minimized.

The black matrix 130 may include an opening overlapping the emission area EA of the plurality of light emitting elements ED. A plurality of metal patterns 140 may be disposed in the opening of the black matrix 130. That is, the plurality of metal patterns 140 is disposed on the third buffer layer 120 so as to overlap the emission area EA of the plurality of light emitting elements ED to improve transmission and reflection performance of the plurality of light emitting elements ED in the emission area EA. For example, the plurality of metal patterns 140 may include at least one selected from the group consisting of bismuth (Bi), nickel (Ni), and titanium (Ti), but is not limited thereto.

A thickness of the plurality of metal patterns 140 may be smaller than a thickness of the black matrix 130. Accordingly, the transmittance in the emission area EA may be improved.

The plurality of metal patterns 140 may include a first portion P1 (also referred to as ‘a basal segment P1’) disposed on the touch sensing unit in the opening of the black matrix 130 and a second portion P2 (also referred to as ‘a sidewall segment P2’) disposed on the side surface of the black matrix 130. Since the plurality of metal patterns 140 is formed at a time using one metal layer, the thickness t1 of the first portion P1 and the thickness t2 of the second portion P2 may be the same.

As the second portion P2 of the plurality of metal patterns 140 is disposed on the side surface of the black matrix 130, light incident in the side surface direction of the black matrix 130 may be reflected by the second portion P2 to change the optical path. For example, light incident in the lateral direction of the black matrix 130 may be reflected from the second portion P2 to be emitted through the opening of the black matrix 130.

Meanwhile, when the plurality of metal patterns is located at a higher layer than the black matrix, external light incident from the outside of the display device may be reflected by the plurality of metal patterns before being absorbed by the black matrix, thereby increasing reflectance in the non-emission area of the light emitting element. Accordingly, in the display device 100 according to the exemplary embodiment of the present disclosure, the plurality of metal patterns 140 may be located on the same layer as the black matrix 130. Accordingly, external light incident from the outside of the display device 100 is absorbed by the black matrix 130 in the non-emission area of the plurality of light emitting elements ED to reduce the reflectance in the non-emission area.

The organic dye layer 150 may be disposed on the plurality of metal patterns 140. For example, the organic dye layer 150 may include a colorant such as a dye or pigment, a monomer, and a polymer material. For example, the organic dye layer 150 includes a polymer material so that the upper surface of the organic dye layer 150 may be planarized. The polymer material included in the organic dye layer 150 may be a polyimide, epoxy, or acrylic polymer material, but is not limited thereto and may be used without being limited as long as it is for planarizing the organic dye layer 150.

The organic dye layer 150 may be formed by an application process such as inkjet or photo. For example, when the organic dye layer 150 is applied by an inkjet method, the black matrix 130 disposed at the outermost side of the display panel may serve as a dam for an inkjet process. Accordingly, the organic dye layer 150 may be disposed to be in contact with the side surface of the black matrix BM at the outermost side of the substrate 110.

The organic dye layer 150 may be integrally disposed to cover the emission area EA and the non-emission area NEA of the plurality of light emitting elements ED. Specifically, the organic dye layer 150 may be integrally formed to correspond to the plurality of sub-pixels SP and configured to have a wavelength that transmits both red light, green light, and blue light. Accordingly, even though the plurality of light emitting elements ED disposed in each of the plurality of sub pixels SP emits red light, green light, or blue light, the organic dye layer 150 may transmit light emitted from each of the plurality of sub pixels SP.

Further, the organic dye layer 150 is integrally formed to correspond to the plurality of sub-pixels SP to simplify the manufacturing process and reduce the process cost and the process time compared to the case where the organic dye layer is separately formed for each sub-pixel.

Meanwhile, the refractive index of the organic dye layer 150 may be different from that of the plurality of metal patterns 140. For example, total reflection is induced by a difference in refractive index at the boundary between the organic dye layer 150 and the plurality of metal patterns 140 to reduce reflection due to external light.

Meanwhile, the second protective layer 160 may be disposed to cover the organic dye layer 150. The second protective layer 160 may be formed of an organic insulating layer. The step on the uppermost layer of the display device 100 may be prevented by the second protective layer 160 to improve the visibility of the display device 100.

Conventionally, a display device having a structure in which a polarizing plate is attached to a display panel has been used. However, when the polarizing plate is separately attached, there is a problem that the thickness of the display device increases. To overcome this, a color filter is disposed in the display panel to replace the polarization layer. However, in this case, there is a problem in that a mask process for patterning the color filter is added as the color filter is disposed for each sub-pixel, thereby increasing process cost and process time. Accordingly, instead of a color filter separated for each sub pixel in the display panel, an organic dye layer integrated in the plurality of sub pixels is disposed, and a metal layer is disposed under the organic dye layer and the black matrix to supplement transmission and reflection performance. Accordingly, it is possible to reduce the thickness of the display device, reduce the mask process, reduce the process cost and the process time, and improve the reflectance due to external light. However, in this case, there is a problem that the metal layer disposed under the black matrix is corroded by the developer of the black matrix.

Accordingly, in the display device 100 according to the exemplary embodiment of the present disclosure, the plurality of metal patterns 140 is disposed on the same layer as the black matrix 130 to correspond to the emission area EA of the plurality of light emitting elements ED, and the organic dye layer 150 is disposed to overlap the emission area EA and the non-emission area NEA of the plurality of light emitting elements ED, thereby preventing corrosion of the plurality of metal patterns 140 and improving reflectance in the emission area EA of the plurality of light emitting elements ED.

Further, in the display device 100 according to the exemplary embodiment of the present disclosure, the organic dye layer 150 integrally formed in the plurality of sub pixels SP is disposed by an application process such as inkjet or photo to reduce the thickness of the display device 100 and reduce process cost and process time by not performing a mask process.

Further, in the display device 100 according to the exemplary embodiment of the present disclosure, the low-temperature black matrix 130 and the black bank 116 are disposed in the non-emission area of the plurality of light emitting elements ED to suppress light emitted from the plurality of light emitting elements ED from being directed to the non-emission area of the plurality of light emitting elements ED. Accordingly, even if the polarization layer is not disposed, reflectance in the non-emission area of the plurality of light emitting elements ED may be reduced, and light leakage defects may be prevented.

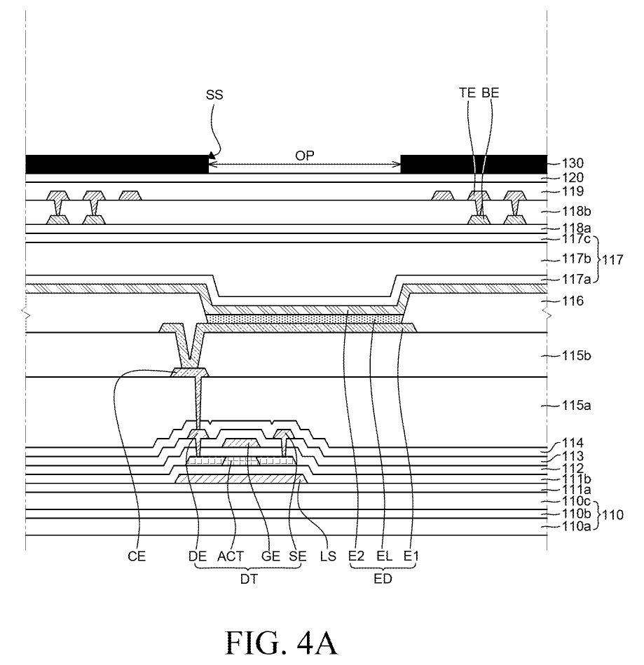

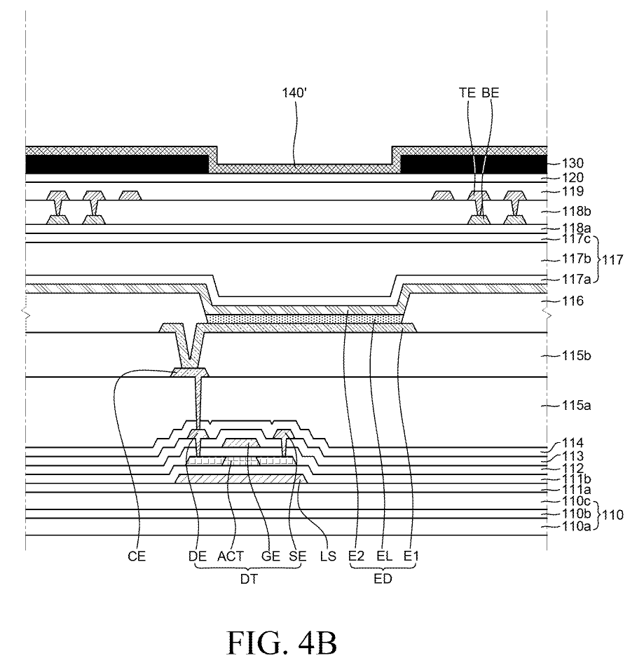

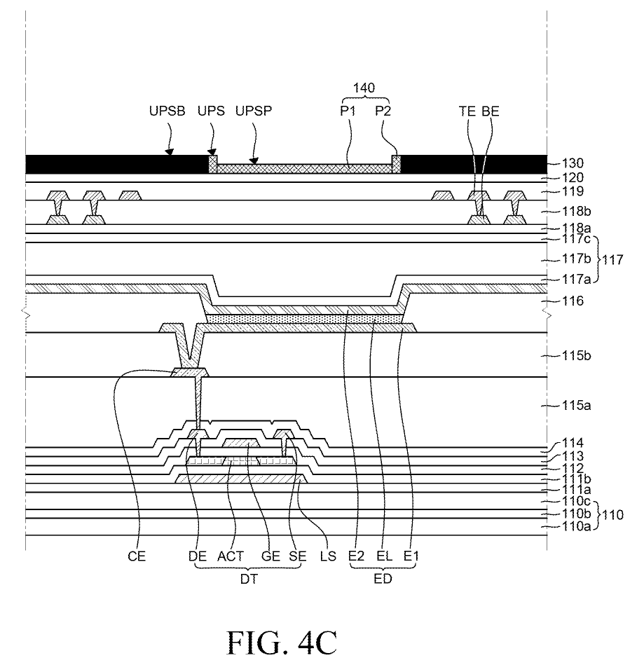

FIGS. 4A to 4C are schematic views illustrating a method of manufacturing a display device according to an exemplary embodiment of the present disclosure. The method of manufacturing the display device of FIGS. 4A to 4C is a method of manufacturing the display device of FIGS. 1 to 3.

First, as illustrated in FIG. 4A, the substrate 110 on which the black matrix 130 is disposed is prepared. The encapsulation structure 117 and the touch sensing part may be disposed on the substrate 110 to cover the plurality of light emitting elements ED, and the first protection layer 119, the third buffer layer 120, and the black matrix 130 may be disposed to cover the touch sensing part. In this case, the black matrix 130 may be patterned to correspond to a non-emission area of the plurality of light emitting elements ED.

Next, as illustrated in 4b, a metal layer 140′ is deposited to cover the black matrix 130.

Thereafter, as illustrated in FIG. 4C, the metal layer 140′ may be polished by a chemical mechanical polishing (CMP) process to form a plurality of metal patterns 140 including the first portion P1 and the second portion P2.

Conventionally, a metal layer is disposed under an organic dye layer and a black matrix to supplement transmission and reflection performance. However, in this case, after forming the black matrix on the metal layer, there is a problem that the metal layer is corroded by a developer used in the patterning process for making the black matrix have a mesh shape.

Accordingly, in the display device 100 according to the exemplary embodiment of the present disclosure, after forming the black matrix 130, the plurality of metal patterns 140 is formed to solve the corrosion problem of the plurality of metal patterns 140 due to the developer of the black matrix 130.

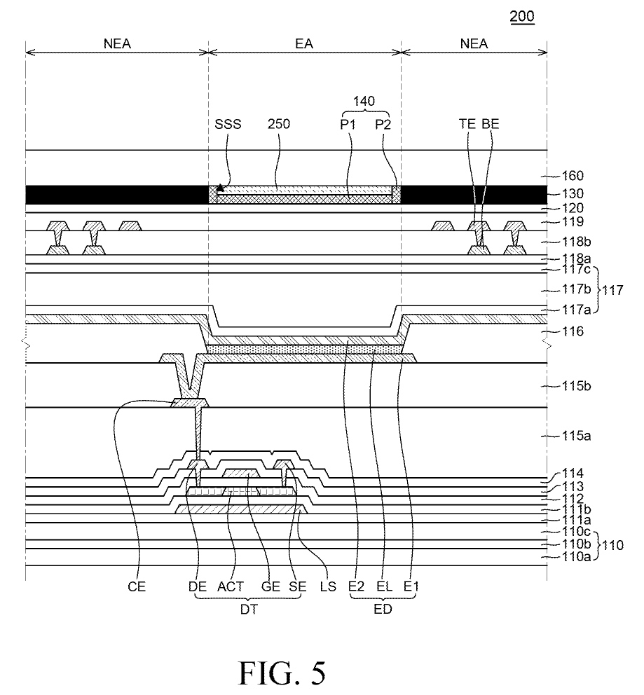

FIG. 5 is a schematic cross-sectional view of a display device according to another embodiment of the present disclosure. The display device 200 of FIG. 5 has the substantially same configuration as the display device 100 of FIGS. 1 to 3, except for the organic dye layer 250, so that a redundant description will be omitted.

Referring to FIG. 5, an organic dye layer 250 may be disposed on a plurality of metal patterns 140.

Specifically, a plurality of organic dye layers 250 may be disposed to be spaced apart from each other so as to correspond to the emission area EA of the plurality of light emitting elements ED. For example, the organic dye layer 250 may be disposed to fill between the top surface of the first portion P1 of the plurality of metal patterns 140 and the side surface of the second portion P2. In this case, the organic dye layer 250 may not be disposed on the upper surface of the black matrix 130. Accordingly, the black visibility when the display device 200 does not emit light may be improved.

For example, a material for forming an organic dye layer is applied to the top surface of the black matrix 130 and then the material for forming an organic dye layer is polished through a chemical mechanical polishing (CMP) process to dispose a plurality of organic dye layers 250 disposed to be spaced apart from each other so as to correspond to the emission area EA of the plurality of light emitting elements ED.

The organic dye layer 250 may be formed to correspond to each of the plurality of sub-pixels SP and configured to have a wavelength that transmits both red light, green light, and blue light. Accordingly, even though the plurality of light emitting elements ED disposed in each of the plurality of sub pixels SP emits red light, green light, or blue light, the organic dye layer 250 may transmit light emitted from each of the plurality of sub pixels SP. However, the present disclosure is not limited thereto, and the organic dye layer 250 may be formed to transmit different wavelengths for each sub pixel SP. For example, the organic dye layer 250 disposed in the sub pixel SP emitting red light may be configured with a wavelength that transmits red light, the organic dye layer 250 disposed in the sub pixel SP emitting green light may be configured with a wavelength that transmits green light, and the organic dye layer 250 disposed in the sub pixel SP emitting blue light may be configured with a wavelength that transmits blue light. For example, when the organic dye layer 250 is configured to have a wavelength that transmits all of red light, green light, and blue light, it may be advantageous in terms of manufacturing process cost and time because it is not necessary to use different dyes for each sub pixel SP.

For example, the organic dye layer 250 may include a colorant such as a dye or pigment, a monomer, and a polymer material. For example, the organic dye layer 250 includes a polymer material so that the upper surface of the organic dye layer 250 may be planarized. The polymer material included in the organic dye layer 250 may be a polyimide, epoxy, or acrylic polymer material, but is not limited thereto and may be used without being limited as long as it is for planarizing the organic dye layer 250.

In the display device 200 according to still another exemplary embodiment of the present disclosure, the plurality of metal patterns 140 is disposed on the same layer as the black matrix to correspond to the emission area EA of the plurality of light emitting elements ED, and the organic dye layer 250 is disposed to overlap the emission area EA of the plurality of light emitting elements ED, thereby preventing corrosion of the plurality of metal patterns 140 and improving reflectance in the emission area EA of the plurality of light emitting elements ED. In addition, since the organic dye layer 250 is disposed so as to overlap the emission area EA of the plurality of light emitting elements ED, the organic dye layer 250 is not disposed on the top surface of the black matrix 130, the black visibility may be improved when the display device 200 does not emit light.

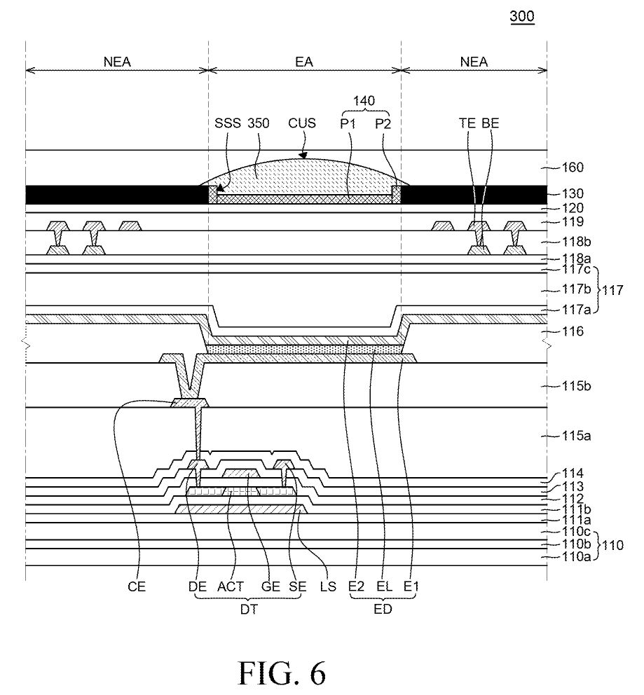

FIG. 6 is a schematic cross-sectional view of a display device according to still another exemplary embodiment of the present disclosure. A display device 300 of FIG. 6 has the substantially same configuration as the display device 100 of FIGS. 1 to 3, except for an organic dye layer 350, so that a redundant description will be omitted.

Referring to FIG. 6, an organic dye layer 350 may be disposed on a plurality of metal patterns 140.

Specifically, a plurality of organic dye layers 350 may be disposed to be spaced apart from each other so as to correspond to the emission area EA of the plurality of light emitting elements ED. For example, the organic dye layer 350 may be disposed to cover the top surface of the first portion P1 of the plurality of metal patterns 140, the top surface of the second portion P2, and at least a part of the black matrix 130. In this case, the organic dye layer 350 may not be disposed on most top surfaces of the black matrix 130. Accordingly, the black visibility when the display device 300 does not emit light may be improved.

For example, a material for forming an organic dye layer is applied to an upper surface of the black matrix 130, and then a pattern is formed through a photo process, and then exposed to the light, such that a plurality of organic dye layers 350 disposed to be spaced apart from each other so as to correspond to the emission areas EA of the plurality of light emitting elements ED may be disposed. For example, when a plurality of organic dye layers 350 are disposed through the photo process, the process time and cost may be reduced compared to disposing a plurality of organic dye layers through the CMP process.

The organic dye layer 350 may be formed to correspond to each of the plurality of sub-pixels SP and configured to have a wavelength that transmits both red light, green light, and blue light. Accordingly, even though the plurality of light emitting elements ED disposed in each of the plurality of sub pixels SP emits red light, green light, or blue light, the organic dye layer 350 may transmit light emitted from each of the plurality of sub pixels SP. However, the present disclosure is not limited thereto, and the organic dye layer 350 may be formed to transmit different wavelengths for each sub pixel SP. For example, the organic dye layer 350 disposed in the sub pixel SP which emits red light may be configured by a wavelength which transmits red light, the organic dye layer 350 disposed in the sub pixel SP which emits green light may be configured by a wavelength which transmits green light, and the organic dye layer 350 disposed in the sub pixel SP which emits blue light may be configured by a wavelength which transmits blue light. For example, when the organic dye layer 350 is configured to have a wavelength that transmits all of red light, green light, and blue light, it may be advantageous in terms of manufacturing process cost and time because it is not necessary to use different dyes for each sub pixel SP.

For example, the organic dye layer 350 may include a colorant such as a dye or pigment, a monomer, and a polymer material. However, the present disclosure is not limited thereto, and the organic dye layer 350 may include only colorants such as dyes and pigments and monomers.

In the display device 300 according to still another exemplary embodiment of the present disclosure, the plurality of metal patterns 140 is disposed on the same layer as the black matrix to correspond to the emission area EA of the plurality of light emitting elements ED, and the organic dye layer 350 is disposed to overlap the emission area EA of the plurality of light emitting elements ED, thereby preventing corrosion of the plurality of metal patterns 140 and improving reflectance in the emission area EA of the plurality of light emitting elements ED. In addition, since the organic dye layer 350 is disposed so as to overlap the emission area EA of the plurality of light emitting elements ED, the organic dye layer 350 is not disposed on the top surface of the black matrix 130, the black visibility may be improved when the display device 300 does not emit light.

In the embodiments described above, the first portion P₁ and the second portion P₂ of each metal pattern 140 are typically formed at a time using one metal layer and therefore may be made of the same metallic material. However, in other embodiments, the first portion P₁ and the second portion P₂ may be formed of different metallic materials. For example, the first portion P₁ may be formed of a metal having high optical reflectivity, such as aluminum (Al) or silver (Ag), while the second portion P₂ may be formed of a metal having superior chemical or mechanical stability, such as nickel (Ni), titanium (Ti), or chromium (Cr). The first and second portions may be formed by sequential deposition of different metals, by selective plating, or by coating or surface modification of one portion after the other is formed. In this manner, the lower horizontal portion P1 of the metal pattern may provide high reflectance to light emitted from the light emitting elements, while the sidewall portion P2 provides enhanced resistance to corrosion or damage during subsequent processing. The first and second portions may be joined along a continuous interface, and together they may form a composite metal structure having substantially uniform thickness and shape across the opening of the black matrix.

Further, although the plurality of metal patterns 140 may generally have the same thickness along the first and second portions, the respective metals may differ in optical and chemical properties according to the desired balance between reflectivity and durability. The embodiments in which the first and second portions are formed of the same or different materials are all within the scope of the present disclosure.

In one embodiment, a display device includes a substrate 110 that provides mechanical support for subsequent layers and elements of the device. A light-emitting element ED is disposed on the substrate 110 within an active region. The light-emitting element may include an anode, a cathode, and an organic emission layer or other emissive stack capable of generating light when current flows between the electrodes. An encapsulation structure 117 is disposed on the light-emitting element to protect the light-emitting element from moisture, oxygen, and other contaminants. The encapsulation structure 117 may include one or more inorganic and organic films, or alternating inorganic and organic layers, collectively forming a barrier stack.

A touch sensing structure is disposed on the encapsulation structure 117. The touch sensing structure may include a plurality of patterned electrodes configured to detect touch input through capacitive, resistive, or optical sensing. A black matrix 130 is disposed on the touch sensing structure and defines a plurality of openings OP corresponding to emission areas EA of the light-emitting element ED. Each opening OP extends into the black matrix 130 and overlaps the corresponding light-emitting element ED in a plan view.

At least one metal pattern 140 is disposed within each opening OP of the black matrix 130. Each metal pattern 140 includes a basal segment P1 extending horizontally relative to the substrate 110 and a sidewall segment P2 extending vertically from an edge of the basal segment P1 along a side surface SS of the black matrix 130 that defines the opening OP. The basal segment P1 lies along a surface of the touch sensing structure (more specifically, an upper surface of the third buffer layer 120), and the sidewall segment P2 extends upward along the interior side surface SS of the black matrix 130, forming a continuous metallic boundary within the opening OP.

In certain embodiments, the basal segment P1 and the sidewall segment P2 are formed as a single continuous metal body without an interface therebetween. The metal pattern 140 may be formed by depositing a metal film (or a metal layer 140’) over the black matrix 130 and performing a planarization or etching process to leave the metal within the openings. As a result, the basal segment P1 and the sidewall segment P2 are integrally formed from the same metal layer and share a common boundary.

In another embodiment, each basal segment P1 extends across a bottom of the opening OP, and each sidewall segment P2 extends continuously from an edge of the basal segment P1 along the side surface SS of the black matrix 130 defining the opening OP. The continuous extension between the basal and sidewall segments provides a uniform reflective surface and ensures stable adhesion between the metal and adjacent layers.

In some embodiments, a vertical dimension VD1 of the sidewall segment P2 is equal to or smaller than a vertical dimension VD2 of the black matrix 130. Limiting the height of the sidewall segment in relation to the black matrix reduces surface irregularities and provides a substantially planar top surface for subsequent layers. In other embodiments, a lateral dimension t2 of the sidewall segment P2 is equal to a vertical dimension t1 of the basal segment P1, thereby forming a substantially uniform metal thickness in both horizontal and vertical directions. The basal and sidewall segments having substantially equal thicknesses may join through a continuous curved transition region at an interface between the touch sensing structure and the side surface SS of the black matrix 130.

In additional embodiments, an upper surface UPS of the sidewall segment P2 is coplanar with an upper surface UPSB of the black matrix 130, thereby forming a substantially level surface across the display stack. In alternative configurations, an upper surface UPSP of the basal segment P1 is recessed relative to the upper surface UPSB of the black matrix 130, providing a step or depression that may enhance optical absorption or planarization uniformity.

In yet another embodiment, the basal segment and the sidewall segment are formed of different metallic materials. For example, the basal segment may include a metal selected for high optical reflectivity, such as aluminum or silver, while the sidewall segment may include a metal selected for chemical stability or corrosion resistance, such as nickel, titanium, or chromium. The first and second metals may be sequentially deposited or selectively plated to form a composite metal structure within the opening of the black matrix.

An organic dye layer 150, 250, 350 may be disposed on the metal pattern 140 within the opening OP of the black matrix 130. The organic dye layer may absorb external light and suppress surface reflections while allowing emitted light from the light-emitting element to pass through. In one embodiment, the organic dye layer covers upper surfaces of the basal segment, the sidewall segment, and the black matrix, thereby forming a continuous film across the emission and non-emission regions (see FIG. 3). In another embodiment, the organic dye layer covers an upper surface of the basal segment and a side surface of the sidewall segment and is spaced apart from the black matrix to form an isolated dye region (see FIG. 5). In still another embodiment, the organic dye layer covers the upper surface of the basal segment, the side surface SSS of the sidewall segment, and an upper surface of the black matrix, and has a varying thickness across the basal segment (see FIG. 6).

The organic dye layer 350 may have a curved upper surface CUS defining a lens-shaped profile across the basal segment. The curvature may result from surface tension or inkjet deposition processes that produce a convex contour. In certain embodiments, the organic dye layer 350 defines a convex lens-shaped contour having a maximum thickness at a central region of the basal segment and a minimum thickness adjacent to the sidewall segment. The convex shape may contribute to improved light distribution and enhanced optical uniformity across the display panel.

The exemplary embodiment of the present disclosure can also be described as follows:

According to an aspect of the present disclosure, a display device includes a substrate including an active area in which a plurality of sub-pixels is disposed and a non-active area surrounding the active area, a plurality of light emitting elements disposed in the plurality of sub-pixels on the substrate, an encapsulation structure disposed to cover the plurality of light emitting elements, a touch sensing unit disposed on the encapsulation structure and including a plurality of touch electrodes, a black matrix disposed on the touch sensing unit, a plurality of metal patterns disposed in an opening of the black matrix, and an organic dye layer disposed on the plurality of metal patterns.

According to another feature of the present disclosure, the thickness of the plurality of metal patterns may be smaller than the thickness of the black matrix.

According to another feature of the present disclosure, the plurality of metal patterns may include a first portion disposed on the touch sensing unit in an opening of the black matrix and a second portion disposed on a side surface of the black matrix, and a thickness of the first portion and a thickness of the second portion may be the same.

According to another feature of the present disclosure, the organic dye layer may be integrally disposed to cover the emission area and the non-emission area of the plurality of light emitting elements.

According to another feature of the present disclosure, a plurality of organic dye layers may be disposed to be spaced apart from each other so as to correspond to emission areas of the plurality of light emitting elements.

According to another feature of the present disclosure, the organic dye layer may be disposed to fill between the upper surface of the first portion and the side surface of the second portion.

According to another feature of the present disclosure, the organic dye layer may be disposed to cover at least a part of the top surface of the first portion, the top surface of the second portion, and the black matrix.

According to another feature of the present disclosure, at the outermost side of the substrate, the organic dye layer may be disposed to contact the side surface of the black matrix.

A display device according to another exemplary embodiment of the present disclosure includes a substrate, a plurality of light emitting elements disposed on the substrate, an encapsulation structure disposed to cover the plurality of light emitting elements, a touch sensing unit disposed on the encapsulation structure and including a plurality of touch electrodes, a black matrix disposed on the touch sensing unit and including an opening overlapping a emission area of the plurality of light emitting elements, a plurality of metal patterns positioned on the same layer as the black matrix and disposed in the opening of the black matrix to overlap the emission area of the plurality of light emitting elements, and an organic dye layer disposed to cover the plurality of metal patterns.

According to another feature of the present disclosure, the thickness of the plurality of metal patterns may be smaller than the thickness of the black matrix.

According to another feature of the present disclosure, the plurality of metal patterns may include a first portion disposed on the touch sensing unit in an opening of the black matrix and a second portion disposed on a side surface of the black matrix, and a thickness of the first portion and a thickness of the second portion may be the same.

According to another feature of the present disclosure, the organic dye layer may be integrally disposed to cover the emission area and the non-emission area of the plurality of light emitting elements.

According to another feature of the present disclosure, a plurality of organic dye layers may be disposed to be spaced apart from each other so as to correspond to emission areas of the plurality of light emitting elements.

According to another feature of the present disclosure, the organic dye layer may be disposed to fill between the upper surface of the first portion and the side surface of the second portion.

According to another feature of the present disclosure, the organic dye layer may be disposed to cover the top surface of the first portion, the top surface of the second portion, and at least a part of the black matrix.

According to another feature of the present disclosure, at the outermost side of the substrate, the organic dye layer may be disposed to contact the side surface of the black matrix.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device comprising:
a substrate including an active area in which a plurality of sub-pixels is disposed and a non-active area adjacent to the active area;
a plurality of light emitting elements disposed in the plurality of sub-pixels on the substrate;
an encapsulation structure disposed to cover the plurality of light emitting elements;
a touch sensing structure disposed on the encapsulation structure and including a plurality of touch electrodes;
a black matrix disposed on the touch sensing structure;
a plurality of metal patterns disposed in an opening of the black matrix; and
an organic dye layer disposed on the plurality of metal patterns.

2. The display device according to claim 1, wherein a thickness of the plurality of metal patterns is smaller than a thickness of the black matrix.

3. The display device according to claim 1, wherein the plurality of metal patterns includes a first portion disposed on the touch sensing structure in an opening of the black matrix and a second portion disposed on a side surface of the black matrix, and
a thickness of the first portion and a thickness of the second portion are the same.

4. The display device according to claim 3, wherein the organic dye layer is integrally disposed to cover an emission area and a non-emission area of the plurality of light emitting elements.

5. The display device according to claim 3, wherein a plurality of organic dye layers are disposed to be spaced apart from each other so as to correspond to emission areas of the plurality of light emitting elements.

6. The display device of claim 5, wherein the organic dye layer is disposed to fill between a top surface of the first portion and a side surface of the second portion.

7. The display device according to claim 5, wherein the organic dye layer is disposed to cover a top surface of the first portion, a top surface of the second portion, and at least a part of the black matrix.

8. The display device according to claim 1, wherein the organic dye layer is disposed at an outermost side of the substrate to be in contact with a side surface of the black matrix.

9. A display device comprising:
a substrate;
a plurality of light emitting elements disposed on the substrate;
an encapsulation structure disposed to cover the plurality of light emitting elements;
a touch sensing structure disposed on the encapsulation structure and including a plurality of touch electrodes;
a black matrix disposed on the touch sensing structure and including an opening overlapping a emission area of the plurality of light emitting elements;
a plurality of metal patterns positioned on the same layer as the black matrix and disposed in the opening of the black matrix to overlap the emission area of the plurality of light emitting elements; and
an organic dye layer disposed to cover the plurality of metal patterns.

10. The display device according to claim 9, wherein the thickness of the plurality of metal patterns is smaller than the thickness of the black matrix.

11. The display device according to claim 10, wherein the plurality of metal patterns includes a first portion disposed on the touch sensing structure in an opening of the black matrix and a second portion disposed on a side surface of the black matrix, and
a thickness of the first portion and a thickness of the second portion are the same.

12. The display device according to claim 11, wherein the organic dye layer is integrally disposed to cover the emission area and the non-emission area of the plurality of light emitting elements.

13. The display device according to claim 11, wherein a plurality of organic dye layers are disposed to be spaced apart from each other so as to correspond to emission areas of the plurality of light emitting elements.

14. The display device according to claim 13, wherein the organic dye layer is disposed to fill between a top surface of the first portion and a side surface of the second portion.

15. The display device according to claim 13, wherein the organic dye layer is disposed to cover the top surface of the first portion, the top surface of the second portion, and at least a part of the black matrix.

16. The display device according to claim 9, wherein the organic dye layer is disposed at an outermost side of the substrate to be in contact with a side surface of the black matrix.

17. A display device comprising:
a substrate;
a light emitting element disposed on the substrate;
an encapsulation structure disposed on the light emitting element;
a touch sensing structure disposed on the encapsulation structure;
a black matrix disposed on the touch sensing structure;
an opening extending into the black matrix, the opening overlapping the light emitting element in a plan view; and
at least one metal pattern disposed within the opening of the black matrix, the at least one metal pattern including a basal segment extending horizontally relative to the substrate and a sidewall segment extending vertically from an edge of the basal segment along a side surface of the black matrix defining the opening.

18. The display device of claim 17, wherein an upper surface of the sidewall segment is coplanar with an upper surface of the black matrix.

19. The display device of claim 17, wherein an upper surface of the basal segment is recessed relative to an upper surface of the black matrix.

20. The display device of claim 17, further comprising:
an organic dye layer disposed on the at least one metal pattern.
